(19) United States
(12) Patent Application Publication
(10) Pub. No.: US 2011/0215744 A1
(43) Pub. Date: Sep. 8, 2011

(54) METHOD FOR DETECTING THE ROTOR POSITION OF AN ELECTRIC MACHINE, AND DEVICE FOR THE SAME

(75) Inventors: Daniel Kocher, Dusslingen (DE); Rolf Jaros, Backnang (DE); Kurt Reutlinger, Stuttgart (DE)

(73) Assignee: ROBERT BOSCH GMBH, Stuttgart (DE)

(21) Appl. No.: 13/061,355

(22) PCT Filed: Jul. 30, 2009
(86) PCT No.: PCT/EP09/59845

§ 371 Date: May 26, 2011

(30) Foreign Application Priority Data
Aug. 26, 2008 (DE) 10 2008 041 549.9

(51) Int. Cl. H02P 6/18; G01R 33/06

(52) U.S. Cl. 318/400.07; 324/207.2

(57) ABSTRACT

The invention relates to a method for providing information on a rotor position of a rotor of an electric machine (2) for utilization in a function connected downstream, comprising the following steps: —determining at least one electric operating variable of a stator winding of the electric machine, particularly a phase current and/or a phase voltage; —determining a rotor position as a function of the electric operating variable—providing information on the rotor position determined as a function of the electric operating variable for the function connected downstream if the rotational speed of the electric machine (2) exceeds a threshold rotational speed (SW).

### BACKGROUND OF THE INVENTION

The invention generally relates to the detection of the rotor position, particularly for electronically commutating an electric motor with the aid of the detected rotor position.

The electronic commutation of electric machines requires knowledge of the absolute angular position of the rotor, the rotor position. The rotor position can be detected by means of suitable sensors such as, e.g., incremental-resolution rotary transducers, Hall sensors etc. Alternative position detection arrangements manage without position sensors by evaluating, e.g., the phase current or the phase voltage of a winding phase of the stator winding and calculating the rotor position by suitable methods. For example, the rotor position can be determined in such a method by evaluating the third harmonic of the variation of a phase current or of a phase voltage with the aid of the “Back-EMF method” and the like.

The methods for detecting the rotor position on the basis of the evaluation of the phase current or of the phase voltage, however, have the disadvantage that they do not, or only with inadequate accuracy, detect the rotor position at low rotational speeds and/or at very high rotational speeds or in the case of a load, so that an electronic commutation based on a rotor position detected in this manner is not reliably possible at low rotational speeds. For example, during the determination of the rotor position by evaluating the third harmonic, the latter is distorted by saturation effects and differences therebetween, as a result of which it becomes unanalyzable. At high rotational speeds, the “Back-EMF method” can no longer be used since there are no longer any currentless time domains in this method.

### SUMMARY OF THE INVENTION

It is the object of the present invention to provide a method and a device for the sensorless determination of the rotor position in which malfunctions of a downstream function such as, e.g., an electronic commutation, due to unreliable information about the rotor position, can be avoided.

According to a first aspect, a method for providing information about a rotor position of a rotor of an electric machine, particularly a synchronous machine, for utilization in a downstream function is provided. The method comprises the following steps: determining at least one electric operating variable of a stator winding of the electric machine, particularly a phase current and/or a phase voltage; determining a rotor position as a function of the electric operating variable; and providing information on the rotor position determined as a function of the electric operating variable for the downstream function if the rotational speed of the electric machine exceeds a threshold rotational speed.

One concept of the invention consists in providing the rotor position determined by an evaluation of the phase current and/or of the phase voltage only at rotational speeds above a threshold value of the rotational speed. In this manner, a rotor position is only provided when it is sufficiently accurate or sufficiently reliable so that electronic commutation of the electric machine is possible.

An electronic commutation of the synchronous machine as a function of the rotor position determined with the aid of the electric operating variable can be carried out as the downstream function.

Furthermore, no rotor position can be determined when the rotational speed of the electric machine does not exceed the threshold rotational speed. In particular, information can be provided which specifies that no information about a rotor position can be provided.

It is thus provided to provide no rotor position information below the threshold value of the rotational speed and, in particular, to suitably communicate information which specifies that no information about a rotor position can be provided, as a result of which it is possible, e.g. for the downstream function to execute a function which manages without information about the rotor position such as, e.g., the implementation of a stepped operation of the electric motor.

In particular, an electronic commutation of the electric machine can be carried out as a function of the rotor position determined with the aid of the electric operating variable as the downstream function, wherein the rotor of the electric machine is operated by controlled start-up, particularly by a drive signal of rising frequency, e.g. for a stepped operation, independently of the provision of information about the rotor position, when the rotational speed of the electric machine does not exceed the threshold rotational speed or information is provided which specifies that no information about a rotor position can be provided.

Furthermore, the method can have the further steps: determining an inductance of one of the stator windings; determining a rotor position as a function of the inductance determined; and providing the rotor position, determined with the aid of the inductance determined, for the downstream function if the rotational speed of the electric machine does not exceed the threshold rotational speed.

By this means, information about the rotor position is provided which is determined by a method for detecting the rotor position which is suitable for detecting the rotor position at lower rotational speeds or at a standstill, i.e. at rotational speeds below the threshold value of the rotational speed.

According to one embodiment, an electronic commutation of the electric machine can be carried out as a function of the rotor position determined with the aid of the electric operating variable as the downstream function when the rotational speed of the electric machine exceeds the threshold rotational speed, wherein an electronic commutation of the electric machine is carried out as a function of the rotor position determined with the aid of the inductance determined as the downstream function if the rotational speed of the electric machine does not exceed the threshold rotational speed.

According to a further aspect, a device for providing information about a rotor position of a rotor of an electric machine for use in a downstream function is provided. The device comprises: a calculating unit for determining at least one electric operating variable of a stator winding of the synchronous machine, particularly a phase current and/or a phase voltage; a converting unit for determining a rotor position as a function of the electric operating variable; and a control unit for driving a selecting unit in order to provide the information about the rotor position, determined as a function of the electric operating variable, for the downstream function when the rotational speed of the electric machine exceeds a threshold rotational speed.

The device can also have an alternative operating unit which is constructed for providing information which specifies that no information about a rotor position can be provided, the control unit being constructed for driving the selecting unit so that the information is provided which specifies that no information about the rotor position can be provided when the rotational speed of the electric machine exceeds a threshold rotational speed.

According to a further aspect, a motor system comprising the above device and an inverter for driving the synchronous motor is provided, the inverter being constructed for carrying out the electronic commutation of the synchronous machine as a function of the rotor position determined with the aid of the electric operating variable when the inverter receives the rotor position determined with the aid of the electric operating variable; and driving the rotor of the electric machine by controlled start-up, in particular by a drive signal of rising frequency, independently of the provision of information about the rotor position when the inverter receives the information which specifies that no information about a rotor position can be provided.

As an alternative, the device can be provided with an alternative operating unit which is constructed for determining an inductance of one of the stator windings, determining a rotor position as a function of the inductance determined and providing information about the rotor position determined with the aid of the inductance determined, the control unit providing the rotor position determined with the aid of the inductance determined, via the selecting unit, to the inverter if the rotational speed of the electric machine does not exceed the threshold rotational speed.

As an alternative, the motor system can be provided with the above device and an inverter for driving the electric machine, the inverter being constructed for carrying out, as downstream function, the electronic commutation of the electric machine as a function of the information provided about the rotor position.

### BRIEF DESCRIPTION OF THE DRAWINGS

In the text which follows, preferred embodiments of the invention will be explained in greater detail with reference to the attached drawings, in which:

FIG. 1 shows a diagrammatic block representation of a motor system having a device for operating an electric machine; and

FIG. 2 shows a diagrammatic block representation of the determination of the rotor position in the motor system of FIG. 1.

### DETAILED DESCRIPTION

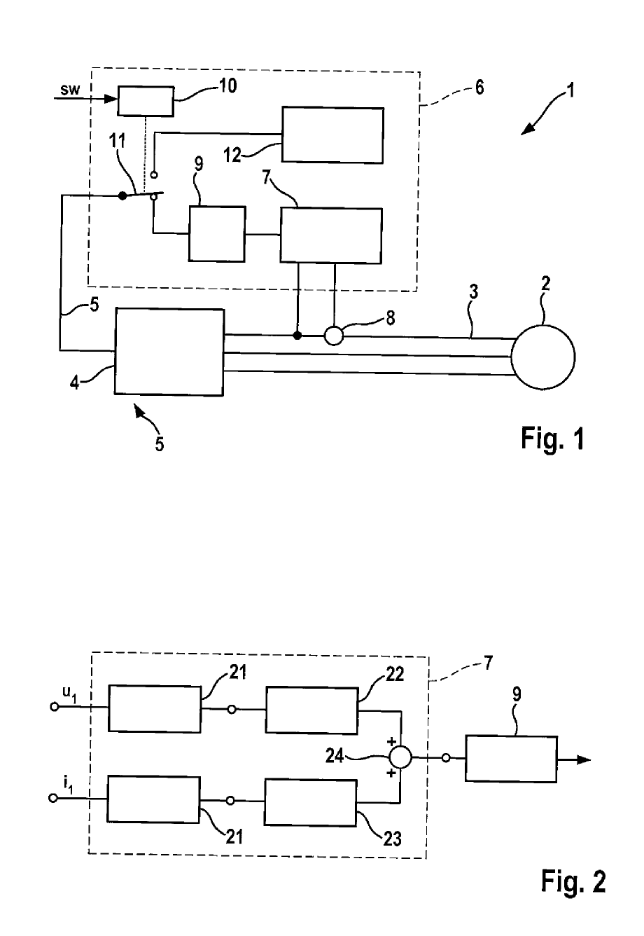

FIG. 1 shows a diagrammatic block representation of a motor system 1 having a synchronous motor 2 as electric machine. The synchronous motor 2 has three phase windings (not shown) which are driven by an inverter 4 by corresponding phase lines 3. The inverter 4 receives an actuating variable S externally which is used for specifying the torque of the synchronous motor. Furthermore, the inverter can also receive information about or a nominal rotational speed (set rotational speed). Furthermore, the inverter 4 receives a drive signal via a signal line 5 for operating the synchronous motor 2.

Furthermore, a control device 6 is provided which outputs the drive signal via the signal line 5 to the inverter 4. The control device 6 comprises a calculating unit 7 for calculating the magnet-wheel flux. For this purpose, the calculating unit 7 receives a phase current from a current detector 8 which has, e.g. a sensing resistor (shunt) and also determines the phase voltage u₁ at the same phase at which the phase current is also determined. The phase voltage can be measured directly or derived from the pulse-width-modulated drive signal, e.g. via the corresponding pulse duty ratio. Phase voltage u₁ and phase current i₁ are provided to the calculating unit 7, which determine the magnet-wheel flux in accordance with the formulae

$$\begin{matrix}{U}_{1} ( t ) = {U}_{p} ( t ) + L \frac{d i ( t )}{d t} + R * l ( t ) & ( 1 ) \\ {U}_{1} ( t ) = {U}_{p} ( t ) + L \frac{d l ( t )}{d t} \\ {ϕ}_{p} ( t ) = {ϕ}_{1} ( t ) - L * {l}_{1} ( t ) \\ with & ( 2 ) \\ ϕ = \int u d t & ( 3 )\end{matrix}$$

Formula (2) corresponds to a voltage equation of one phase of a permanent-magnet-excited machine (according to formula (1)) by neglecting the resistive voltage drop with respect to the other voltage components. Integrating formula (1) provides the flux concatenations in the machine (formula (3)), this being a reduced formula of the mathematical machine model. The main flux φ₁(t) represents the integral over the phase voltage u₁(t). High-frequency components in the terminal voltage which are produced, e.g., by the PWM timing of the inverter have a distinctly lower share after the integration. The high-frequency voltage components have a lower share in the total flux linkage φ₁ (t) corresponding to the frequency. The magnet-wheel flux φ_{P}(t) is accordingly calculated from the integrated phase voltage u₁(t) in the phase current i₁(t) which is multiplied by the factor of the winding inductance L.

The magnet-wheel flux φ_{P}(t) thus determined can be correlated with a rotor position. Converting the magnet-wheel flux into the rotor position is carried out in the converting unit 9. Determining the rotor position via the magnet-wheel flux is particularly appropriate when there are no gaps in the phase currents, i.e. when the phase windings of the synchronous motor are permanently supplied with current (e.g. sinusoidal current supply).

FIG. 2 shows a diagrammatic block representation of the calculating unit 7 and of the converting unit 9. The calculating unit 7 in each case adapts the received voltage signal and received current signal in signal adaptation units 21 and integrates the adapted voltage signal U₁′ in an integration block 22 and amplifies the adapted current signal i₁′ in an amplification block 23. The outputs of the integration block 22 and of the amplification block 23 are added in an adding block 24. In the converting unit 9, the value at the output of the adding block 24 is correlated with a rotor position.

Furthermore, a change-over switch 11 controlled by a control unit 10 (selecting unit) is provided which is switched in such a manner that at a rotational speed of the synchronous motor 2 which is above a predetermined rotational speed threshold value SW, the rotor position determined by the converting unit 9 is transmitted to the inverter 4 via the signal line 5. In this case, the inverter 4 carries out electronic commutation of the synchronous motor 2 on the basis of the rotor position determined.

The rotational speed is determined from the detected phase current which is sinusoidal. The duration of a period is proportional to the rotational speed of the synchronous motor 2.

The threshold rotational speed value SW is preferably selected in such a manner that it specifies the lowest possible rotational speed at which the determination of the rotor position based on the phase current and/or the phase voltage still produces a sufficiently reliable value which allows electronic commutation.

If the control unit 10 notices that the rotational speed of the synchronous motor 2 does not exceed the threshold rotational value SW, the change-over switch 11 is switched in such a manner that the signal line 5 is connected to an output of an alternative operating unit 12. The alternative operating unit 12 can provide that at rotational speeds of the synchronous motor 2 below the threshold rotational speed value SW, as is the case, for example, during a start phase of the synchronous motor 2, initially a controlled start-up of the synchronous motor 2 is effected. For this purpose, a control circuit for operating the synchronous motor 2 at low rotational speeds such as, e.g., a ramp circuit, can be provided in the alternative operating unit 12, which control circuit outputs a frequency drive signal of uniform or rising frequency for the inverter 4 via the signal line 5. The frequency drive signal is suitable for allowing the synchronous motor 2 to start at rising frequency until a certain rotational speed which is specified by the frequency of the frequency drive signal transmitted via the signal line 5 is exceeded. The frequency drive signal with uniform frequency is suitable for operating the synchronous motor 2 at a rotational speed corresponding to the frequency, e.g. in stepped operation.

If the ramp circuit of the alternative operating unit 12 has reached a frequency which represents a rotational speed of the synchronous motor 2 which corresponds to the threshold rotational speed value SW or exceeds it, the control unit 10 switches the change-over switch 11 so that the rotor position determined and output by the converting unit 9 is transmitted via the signal line 5 to the inverter 4 instead of the frequency drive signal. From the type of signal transmitted via the signal line 5, the inverter 4 recognizes whether it is a frequency drive signal of the alternative operating unit 12 or rotor position information from the converting unit 9. This can take place, for example, in the inverter, e.g. in a corresponding differentiating unit (not shown), due to the fact that it is recognized whether the received signal is an analog frequency drive signal or whether it is digital rotor position information when the rotor position information is provided in digital form.

If the inverter 4 receives the frequency drive signal, the inverter generates frequency signals phase-displaced for the three phase lines for driving the synchronous motor 2. If the inverter 4 instead receives the rotor position information, the inverter 4 will carry out electronic commutation on the basis of the rotor position information and as a function of the actuating variable S. As an alternative, information about the switched position of the change-over switch 11 or another signal can be used for indicating the type of information transmitted, via the signal line, to the inverter 4. According to a further alternative, the inverter can also be operated in a timed manner in accordance with a specification via the signal line 5, wherein the timing can be predetermined by the converting unit 9 or the alternative operating unit 12.

In an alternative embodiment, it can be provided that the alternative operating unit 12 also provides rotor position information, the rotor position being determined via another sensorless method. For example, the alternative operating unit 12 can determine a rotor position with the aid of the test pulse method which detects asymmetries of the rotor and uses them for determining the rotor position by correlation. In the case of the test pulse method, the inductance of a stator coil (stator winding) changes as a function of the position of the rotor. Since the rotor has different inductances in the longitudinal and transverse direction due to its structure, the variation in the inductance of a stator coil is characteristic over one rotation of the rotor so that the rotor position can be detected by this means by comparing it with previously learnt or provided inductance profiles. However, the test pulse method is suitable for determining the rotor position with a stationary rotor or at low rotational speeds of the rotor. The test pulse method thus presents a good supplement to those methods for determining the rotor position which are based on the variation of the measurement of a phase current and/or of a phase voltage and can therefore only be applied at higher rotational speeds.

As an alternative, the operation of the controlled start-up of the synchronous motor 2 can also be completely implemented in the inverter 4, the alternative operating unit 12 only outputting a particular signal which is received by the inverter 4 via the signal line 5. By means of the signal determined, it is possible to signal to the inverter 4 that the controlled start-up should now be activated. The control unit 10 can then carry out the switching of the change-over switch 11 in a time controlled manner, the period of time during which the alternative operating unit 12 applies the particular signal to the inverter 4 being selected as a function of the time in which the synchronous motor has probably reached the necessary rotational speed which is necessary for carrying out an electronic commutation on the basis of the rotor position determined by the calculating unit 7 and the converting unit 9.

1. A method for providing information about a rotor position of a rotor of an electric machine (2), for utilization in a downstream function, comprising the following steps: determining at least one electric operating variable of a stator winding of the electric machine, determining a rotor position as a function of the electric operating variable; and providing information on the rotor position determined as a function of the electric operating variable for the downstream function if the rotational speed of the electric machine (2) exceeds a threshold rotational speed (SW).

2. The method as claimed in claim 1, wherein an electronic commutation of the electric machine (2) is carried out as a function of the rotor position determined with the aid of the electric operating variable as the downstream function.

3. The method as claimed in claim 1, wherein no rotor position is determined when the rotational speed of the electric machine does not exceed the threshold rotational speed (SW).

4. The method as claimed in claim 3, wherein information is provided which specifies that no information can be provided about a rotor position.

5. The method as claimed in claim 3, wherein an electronic commutation of the electric machine (2) is carried out as a function of the rotor position determined with the aid of the electric operating variable as the downstream function, wherein the rotor of the electric machine (2) is operated by controlled start-up, particularly by a drive signal of rising frequency independently of the provision of information about the rotor position, when the rotational speed of the electric machine (2) does not exceed the threshold rotational speed (SW) or information is provided which specifies that no information about a rotor position can be provided.

6. The method as claimed in claim 1, comprising the further steps:
determining an inductance of one of the stator windings; determining a rotor position as a function of the inductance determined; and providing the rotor position, determined with the aid of the inductance determined, for the downstream function if the rotational speed of the electric machine (2) does not exceed the threshold rotational speed (SW).

7. The method as claimed in claim 6, wherein an electronic commutation of the electric machine (2) is carried out as a function of the rotor position determined with the aid of the electric operating variable as the downstream function when the rotational speed of the electric machine (2) exceeds the threshold rotational speed (SW), wherein an electronic commutation of the electric machine (2) is carried out as a function of the rotor position determined with the aid of the inductance determined as the downstream function if the rotational speed of the electric machine (2) does not exceed the threshold rotational speed (SW).

8. A device (6) for providing information about a rotor position of a rotor of a synchronous machine for use in a downstream function, comprising: a calculating unit (7) for determining at least one electric operating variable of a stator winding of the electric machine (2; a converting unit (9) for determining a rotor position as a function of the electric operating variable; and a control unit (10) for driving a selecting unit (11) in order to provide the information about the rotor position, determined as a function of the electric operating variable, for the downstream function when the rotational speed of the electric machine (2) exceeds a threshold rotational speed (SW).

9. The device (6) as claimed in claim 8, comprising an alternative operating unit (12) which is constructed for providing information which specifies that no information about a rotor position can be provided, the control unit (10) being constructed for driving the selecting unit (11) so that the information is provided which specifies that no information about the rotor position can be provided when the rotational speed of the electric machine (2) exceeds a threshold rotational speed (SW).

10. (canceled)

11. The device (6) as claimed in claim 8, comprising an alternative operating unit (12) which is constructed for determining an inductance of one of the stator windings, determining a rotor position as a function of the inductance determined and providing information about the rotor position determined with the aid of the inductance determined, the control unit (10) providing the rotor position determined with the aid of the inductance determined, via the selecting unit (11), to the inverter (4) if the rotational speed of the electric machine (2) does not exceed the threshold rotational speed (SW).

12. The device (6) as claimed in claim 11, comprising and an inverter (4) for driving the electric machine (2), the inverter (4) being constructed for carrying out, as the downstream function, the electronic commutation of the electric machine (2) as a function of the information provided about the rotor position.

13. A motor system (1) comprising: a device (6) for providing information about a rotor position of a rotor of a synchronous machine for use in a downstream function, the device comprising a calculating unit (7) for determining at least one electric operating variable of a stator winding of the electric machine (2), a converting unit (9) for determining a rotor position as a function of the electric operating variable, and a control unit (10) for driving a selecting unit (11) in order to provide the information about the rotor position, determined as a function of the electric operating variable, for the downstream function when the rotational speed of the electric machine (2) exceeds a threshold rotational speed (SW).

14. The motor system (1) as claimed in claim 13, wherein the device (6) comprises an alternative operating unit (12) which is constructed for providing information which specifies that no information about a rotor position can be provided, the control unit (10) being constructed for driving the selecting unit (11) so that the information is provided which specifies that no information about the rotor position can be provided when the rotational speed of the electric machine (2) exceeds a threshold rotational speed (SW).

15. The motor system (1) as claimed in claim 14, wherein the device (6) comprises an inverter (4) for driving the electric machine (2), the inverter (4) being constructed for carrying out the electronic commutation of the electric machine (2) as a function of the rotor position determined with the aid of the electric operating variable when the inverter (4) receives the rotor position determined with the aid of the electric operating variable, and driving the rotor of the electric machine (2) by controlled start-up, independently of the provision of information about the rotor position when the inverter (4) receives the information which specifies that no information about a rotor position can be provided.

16. The motor system (1) as claimed in claim 13, wherein the device (6) comprises an alternative operating unit (12) which is constructed for determining an inductance of one of the stator windings, determining a rotor position as a function of the inductance determined and providing information about the rotor position determined with the aid of the inductance determined, the control unit (10) providing the rotor position determined with the aid of the inductance determined, via the selecting unit (11), to the inverter (4) if the rotational speed of the electric machine (2) does not exceed the threshold rotational speed (SW).

17. The motor system (1) as claimed in claim 16, wherein the device (6) comprises an inverter (4) for driving the electric machine (2), the inverter (4) being constructed for carrying out, as the downstream function, the electronic commutation of the electric machine (2) as a function of the information provided about the rotor position.

18. The method as claimed in claim 1, wherein the electric operating variable is a phase current (i₁), a phase voltage (u₂), or both.

19. The device (6) as claimed in claim 8, wherein the electric operating variable is a phase current (i₁), a phase voltage (u₂), or both.

20. The motor system (1) as claimed in claim 13, wherein the controlled start-up is by a drive signal of rising frequency.
